(19) United States
(12) Patent Application Publication
(10) Pub. No.: US 2013/0320504 A1
(43) Pub. Date: Dec. 5, 2013

(54) SEMICONDUCTOR INTEGRATED CIRCUIT APPARATUS HAVING THROUGH SILICON VIAS

(71) Applicants: Jun Ho LEE, Icheon-si (KR); Hyun Seok KIM, Icheon-si (KR); Boo Ho JUNG, Icheon-si (KR); Sun Ki CHO, Icheon-si (KR); Yang Hee KIM, Icheon-si (KR); Young Won KIM, Icheon-si (KR)

(72) Inventors: Jun Ho LEE, Icheon-si (KR); Hyun Seok KIM, Icheon-si (KR); Boo Ho JUNG, Icheon-si (KR); Sun Ki CHO, Icheon-si (KR); Yang Hee KIM, Icheon-si (KR); Young Won KIM, Icheon-si (KR)

(73) Assignee: SK HYNIX INC., Icheon-si (KR)

(21) Appl. No.: 13/600,664

(22) Filed: Aug. 31, 2012

(30) Foreign Application Priority Data
May 30, 2012 (KR) 10-2012-0057329

(51) Int. Cl. H01L 23/50

(52) U.S. Cl. 257/621; 257/E23.079

(57) ABSTRACT

A semiconductor integrated circuit apparatus includes a semiconductor substrate, a plurality of through-silicon vias (TSVs) formed in the semiconductor substrate, and an impedance path blocking unit located between the plurality of TSVs.

### CROSS-REFERENCES TO RELATED APPLICATION

The present application claims priority under 35 U.S.C. §119(a) to Korean application number 10-2012-0057329, filed on May 30, 2012, in the Korean Intellectual Property Office, which is incorporated herein by reference in its entirety.

### BACKGROUND

1. Technical Field

The present invention relates to a semiconductor integrated circuit apparatus, and more particularly, to a semiconductor integrated circuit apparatus having through-silicon vias (TSVs).

2. Related Art

Recently, the capacity and speed of a semiconductor memory used as a memory apparatus in most electronic systems has significantly increased. Furthermore, various attempts have been made to mount a memory having a larger capacity within a smaller area and to efficiently drive the mounted memory.

In order to improve the degree of integration of a semiconductor memory, a three-dimensional arrangement method has been applied based on an existing two-dimensional arrangement method.

The three-dimensional arrangement method is also applied to the semiconductor package field. Currently, research is being actively conducted on TSVs which are formed through stacked semiconductor chips so as to interface the semiconductor chips.

TSVs are formed by forming via holes through a semiconductor substrate (chip) and burying a conductive material in the via holes.

However, as the TSVs are formed inside the semiconductor substrate made of silicon, a signal transmission loss in a high-frequency band may occur due to internal resistance of the semiconductor substrate.

In particular, analog impedance components such as resistance (R), inductance (L), and capacitance (C) exist inside the semiconductor substrate between a TSV for transmitting a signal and a TSV for transmitting a ground voltage. When a path is formed therebetween, high-frequency signal transmission characteristics are degraded.

### SUMMARY

In one embodiment of the present invention, a semiconductor integrated circuit apparatus includes: a semiconductor substrate; a plurality of TSVs formed in the semiconductor substrate; and an impedance path blocking unit located between the plurality of TSVs.

In another embodiment of the present invention, a semiconductor integrated circuit apparatus includes: a semiconductor substrate; first to fourth TSVs formed through the semiconductor substrate; and a dummy via arranged at substantially a same distance from the first to fourth TSVs, and configured to block parasitic impedance paths between the first to fourth TSVs, respectively.

In another embodiment of the present invention, a semiconductor integrated circuit apparatus includes: a plurality of signal transmission members embedded in a semiconductor substrate; and a floating conductive member located between the plurality of signal transmission member.

### BRIEF DESCRIPTION OF THE DRAWINGS

Features, aspects, and embodiments are described in conjunction with the attached drawings, in which:

FIG. 1 is a perspective view of a semiconductor integrated circuit apparatus according to one embodiment of the present invention;

FIG. 2 is a plan view of the semiconductor integrated circuit apparatus according to an embodiment of the present invention;

FIG. 3 is a perspective view of a TSV or dummy via according to an embodiment of the present invention;

FIG. 4 is a plan view of a semiconductor substrate having a plurality of TSVs and a dummy via according to another embodiment of the present invention; and

FIG. 5 is a cross-sectional view illustrating an internal parasitic path of the semiconductor substrate having a dummy via formed therein according to an embodiment of the present invention, taken along line V-V′ of FIG. 4.

### DETAILED DESCRIPTION

Hereinafter, a semiconductor integrated circuit apparatus according to the present invention will be described below with reference to the accompanying drawings through example embodiments.

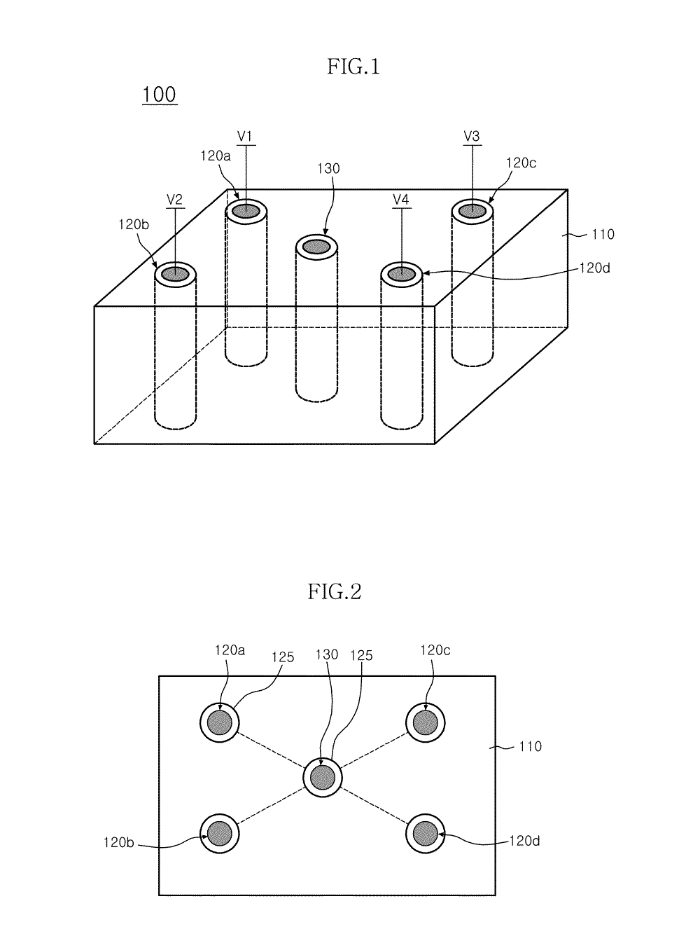

FIG. 1 is a perspective view of a semiconductor integrated circuit apparatus according to one embodiment of the present invention.

Referring to FIG. 1, the semiconductor integrated circuit apparatus 100 includes a semiconductor substrate 110, a plurality of TSVs 120a to 120d, and a dummy via 130.

The semiconductor substrate 110 may include a silicon wafer, for example.

As known from the name, the plurality of TSVs 120a to 120d are formed through the semiconductor substrate 110. The plurality of TSVs 120a to 120d may be arranged at a predetermined distance from each other, in order to reduce a signal influence or interference therebetween. Furthermore, voltages V1 to V4 having different levels may be applied to the TSVs 120a to 120d, respectively. One or more of the TSVs 120a to 120d may act as signal transmission members.

The dummy via 130 serving as an impedance path blocking unit has substantially the same shape as the TSVs 120a to 120d. Furthermore, the dummy via 130 is located between the TSVs 120a to 120d. The dummy via 130 may act as a floating conductive member and thus, may maintain a floating state in which no power is applied. Accordingly, the dummy via 130 may block parasitic resistance paths formed between the TSVs 120a to 120d having a voltage difference.

FIG. 2 is a plan view of the semiconductor substrate having the plurality of TSVs and the dummy via according to an embodiment of the present invention.

Referring to FIG. 2, the dummy via 130 may be arranged inside a region surrounded by the plurality of TSVs 120a to 120d. Desirably, the dummy via 130 serves to block a resistance path between the TSVs facing each other, that is, the plurality of TSVs 120a to 120d surrounding the dummy via 130.

As such, when the dummy via 130 is formed in the center and/or approximate center of the region surrounded by the plurality of TSVs 120a to 120d, the resistance paths formed between the TSVs 120a to 120d may be uniformly controlled by the dummy via 130.

Accordingly, since a plurality of dummy vias do not need to be formed, it is possible to increase a degree of chip integration.

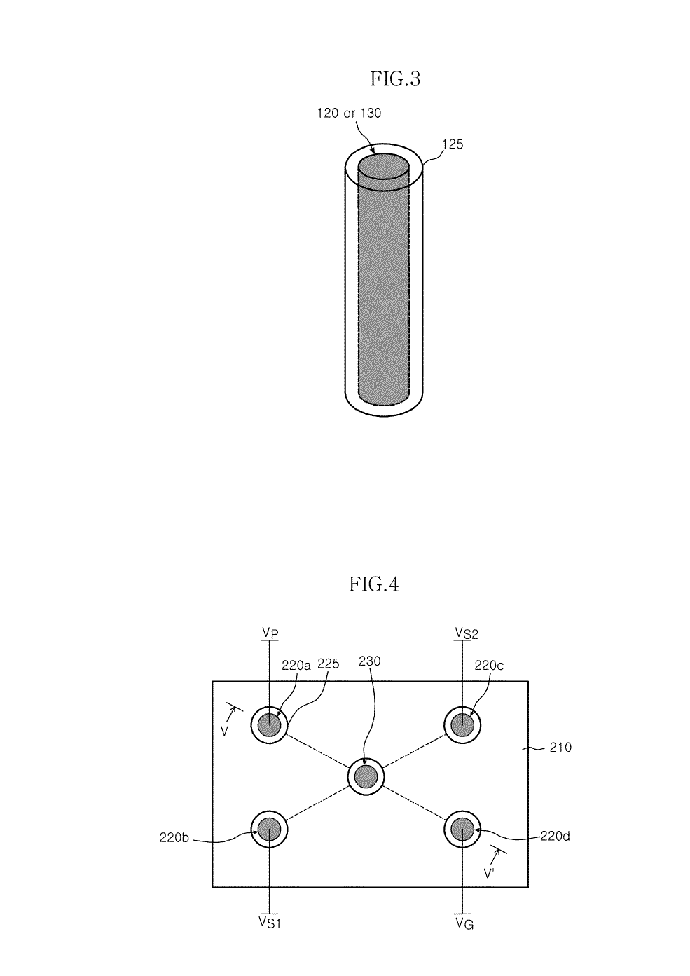

Referring to FIG. 3, each of the TSVs 120a to 120d and the dummy via 130 may be surrounded by an insulation layer 125 to insulate the via from the semiconductor substrate. As FIG. 3 shows, in an embodiment, a construction of the dummy via 130 and the TSVs 120a to 120d may be substantially similar and/or the same

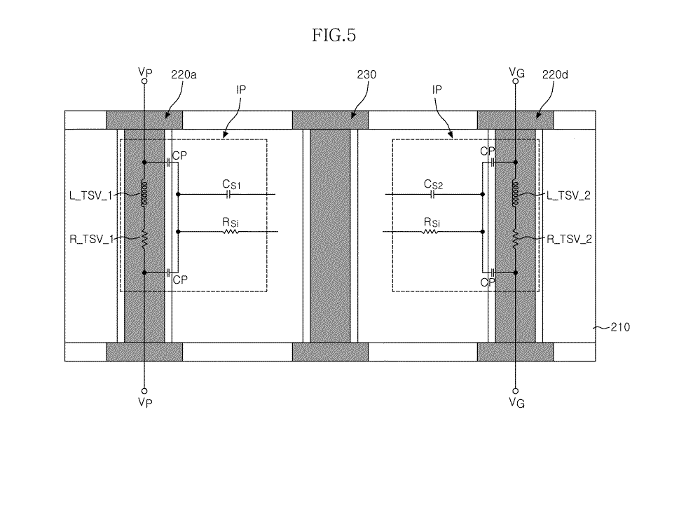

FIG. 4 is a plan view of a semiconductor substrate having a plurality of TSVs and a dummy via according to another embodiment of the present invention.

Referring to FIG. 4, first to fourth TSVs 220a to 220d are arranged at predetermined positions of the semiconductor substrate 210.

The first to fourth TSVs 220a to 220d may be arranged in a rectangular shape, for example. Without being limited thereto, however, the first to fourth TSVs 220a to 220d may be arranged in various other shapes and/or configurations. The first TSV 220a may receive a power voltage VP, the second TSV 220b may receive a first address signal voltage Vs1, the third TSV 220c may receive a second address signal voltage Vs2, and the fourth TSV 220d may receive a ground voltage Vg. Accordingly, a voltage difference may occur between the first to fourth TSVs 220a to 220d, respectively.

The dummy via 230 may be formed in a region surrounded by the first to fourth TSVs 220a to 220d. For example, the dummy via 230 may be arranged in the center of the region surrounded by the first to fourth TSVs 220a to 220d so as to be spaced at a same and/or substantially same distance from the TSVs 220a to 220d, respectively. As the dummy via 230 maintains a constant distance from the first to fourth TSVs 220a to 220d receiving different voltages, the dummy vias 230 may block analog resistance paths formed between the first to fourth TSVs 220a to 220d, respectively, without being influenced by a specific voltage.

Depending on embodiments, dummy vias may be also formed between the first and second TSVs 220a and 220b, between the second and third TSVs 220b and 220c, between the third and fourth TSVs 220c and 220d, and/or between the fourth and first TSVs 220d and 220a, respectively. However, it may be difficult to form the dummy via 230 between the first and second TSVs 220a and 220b, between the second and third TSVs 220b and 220c, between the third and fourth TSVs 220c and 220d, and/or between the fourth and first

TSVs 220d and 220a, respectively, because the distances therebetween may be small. Furthermore, although mutual impedances are coupled as the TSVs are formed with small distances set therebetween, there is no problem in signal transmission, because paths have a small length.

FIG. 5 is a cross-sectional view illustrating an internal parasitic path of the semiconductor substrate having the dummy via formed therein according to an embodiment of the present invention, taken along line V-V′ of FIG. 4.

Referring to FIG. 5, the first and fourth TSVs 220a and 220d have inductances L_TSV_1 and L_TSV_2 and resistances R_TSV_1 and R_TSV_2, respectively.

The inductances L_TSV_1 and L_TSV_2 and the resistances R_TSV_1 and R_TSV_2 of the first and fourth TSVs 220a and 220d are connected to a parasitic capacitance Cp formed between the substrate 210 and the TSVs 220a and 220d, and additionally connected to a substrate capacitance Csi and a substance resistance Rsi, thereby forming a parasitic impedance path Ip.

Furthermore, the parasitic impedance path Ip may be connected to a parasitic impedance path Ip of another TSV adjacent thereto, thereby forming a large impedance path to hinder signal transmission.

In this embodiment of the present invention, however, as the dummy via 230 maintaining a floating state is formed between the TSVs 220a and 220d having a voltage difference, the connection of the impedance path Ip between the TSVs 220a and 220d is cut off. Accordingly, the impedance path is separated into unit impedances, and a signal transmission characteristic is improved in a high-frequency region.

One or more of the TSVs 220a to 220d may include an external terminal which may be electrically connected to circuit terminals (not shown) formed over the semiconductor substrate. In accordance with an embodiment of the present invention, as the dummy via maintaining a floating state is formed between a plurality of TSVs having a voltage difference, and thus an impedance coupling may be prevented. Accordingly, it is possible to prevent high-frequency signal delay.

Furthermore, since the dummy via may be fabricated at the same time as the plurality of TSVs, it is possible to improve the signal delay characteristic without a separate fabrication process.

While certain embodiments have been described above, it will be understood to those skilled in the art that the embodiments described are by way of example only. Accordingly, the semiconductor integrated circuit apparatus described herein should not be limited based on the described embodiments. Rather, the semiconductor integrated circuit apparatus described herein should only be limited in light of the claims that follow when taken in conjunction with the above description and accompanying drawings.

What is claimed is:

1. A semiconductor integrated circuit apparatus comprising:
a semiconductor substrate;
a plurality of through-silicon vias (TSVs) formed in the semiconductor substrate; and
an impedance path blocking unit located between the plurality of TSVs.

2. The semiconductor integrated circuit apparatus according to claim 1, wherein the impedance path blocking unit comprises a dummy via formed in the semiconductor substrate and having a substantially similar structure as the TSVs.

3. The semiconductor integrated circuit apparatus according to claim 2, wherein the dummy via is in a floating state.

4. The semiconductor integrated circuit apparatus according to claim 1, wherein the impedance path blocking unit is formed at substantially the same distance from respective TSVs having a voltage difference.

5. The semiconductor integrated circuit apparatus according to claim 1, wherein the impedance path blocking unit is formed in a center of a region surrounded by the TSVs.

6. The semiconductor integrated circuit apparatus according to claim 1, wherein the plurality of TSVs have a voltage difference from each other.

7. A semiconductor integrated circuit apparatus comprising:
a semiconductor substrate;
first to fourth TSVs formed through the semiconductor substrate; and
a dummy via arranged at substantially a same distance from the first to fourth TSVs, and configured to block parasitic impedance paths between the first to fourth TSVs, respectively.

8. The semiconductor integrated circuit apparatus according to claim 7, wherein the dummy via a substantially similar structure as the first to fourth TSVs.

9. The semiconductor integrated circuit apparatus according to claim 8, further comprising an insulation layer interposed between the dummy via and the semiconductor substrate and insulation layers interposed between the first to fourth TSVs and the semiconductor substrate, respectively.

10. The semiconductor integrated circuit apparatus according to claim 7, wherein the dummy via is in a floating state.

11. The semiconductor integrated circuit apparatus according to claim 7, wherein the first TSV receives a power voltage, the second and third TSVs receive voltages different from each other, and the fourth TSV receives a ground voltage.

12. The semiconductor integrated circuit apparatus according to claim 11, wherein the first to fourth TSVs are arranged in a rectangular shape, and the dummy via is arranged in the approximate center of the rectangular shape.

13. A semiconductor integrated circuit apparatus comprising:
a plurality of signal transmission members embedded in a semiconductor substrate; and
is a floating conductive member located between the plurality of signal transmission member.

14. The semiconductor integrated circuit apparatus according to claim 13, wherein the signal transmission members are formed through the semiconductor substrate and configured to electrically connect an external signal terminal and circuit terminals formed over the semiconductor substrate.

15. The semiconductor integrated circuit apparatus according to claim 14, wherein the floating conductive member has a substantially similar shape as the signal transmission members, and is connected to no voltage source.

16. The semiconductor integrated circuit apparatus according to claim 15, wherein the signal transmission members and the floating conductive member are electrically insulated from the semiconductor substrate.

17. The semiconductor integrated circuit apparatus according to claim 13, wherein the plurality of signal transmission members having the floating conductive member interposed therebetween have a voltage difference.
